(19) United States
(12) Patent Application Publication
(10) Pub. No.: US 2024/0105508 A1
(43) Pub. Date: Mar. 28, 2024

(54) INTEGRATED CIRCUIT DEVICES WITH CONTACTS USING NITRIDIZED MOLYBDENUM

(71) Applicant: Intel Corporation, Santa Clara, CA (US)

(72) Inventors: Jitendra Kumar Jha, Hillsboro, OR (US); Justin Mueller, Portland, OR (US); Nazila Haratipour, Portland, OR (US); Gilbert W. Dewey, Beaverton, OR (US); Chi-Hing Choi, Portland, OR (US); Jack T. Kavalieros, Portland, OR (US); Siddharth Chouksey, Portland, OR (US); Nancy Zelick, Portland, OR (US); Jean-Philippe Turmaud, Portland, OR (US); I-Cheng Tung, Hillsboro, OR (US); Blake Bluestein, Hillsboro, OR (US)

(73) Assignee: Intel Corporation, Santa Clara, CA (US)

(21) Appl. No.: 17/935,647

(22) Filed: Sep. 27, 2022

(51) Int. Cl. H01L 21/768; H01L 29/49

(52) U.S. Cl. CPC H01L 21/76856; H01L 21/76837; H01L 21/76877; H01L 29/4908

(57) ABSTRACT

Disclosed herein are integrated circuit (IC) devices with contacts using nitridized molybdenum. For example, a contact arrangement for an IC device may include a semiconductor material and a contact extending into a portion of the semiconductor material. The contact may include molybdenum. The molybdenum may be in a first layer and a second layer, where the second layer may further include nitrogen. The first layer may have a thickness between about 5 nanometers and 16 nanometers, and the second layer may have a thickness between about 0.5 nanometers to 2.5 nanometers. The contact may further include a fill material (e.g., an electrically conductive material) and the second layer may be in contact with the fill material. The molybdenum may have a low resistance, and thus may improve the electrical performance of the contact. The nitridized molybdenum may prevent oxidation during the fabrication of the contact.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of electrodes (or contacts) in IC devices may help with such an optimization.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of an example contact arrangement with nitridized molybdenum, according to various embodiments of the present disclosure.

FIG. 2 is a cross-sectional side view of an example contact arrangement with nitridized molybdenum, according to various embodiments of the present disclosure.

FIGS. 3A-3C provide cross-sectional side views of example transistors having source and/or drain (S/D) contacts with nitridized molybdenum, according to various embodiments of the present disclosure.

FIGS. 4A-4C are a cross-sectional side views of an example IC device having contacts with nitridized molybdenum, according to various embodiments of the present disclosure.

FIG. 5 is a flow diagram of an example method of manufacturing an IC device with contacts using nitride molybdenum, according to some embodiments of the disclosure.

FIG. 6 is a flow diagram of an example method of manufacturing an IC device with contacts using nitride molybdenum, according to some embodiments of the disclosure.

FIG. 7 illustrates top views of a wafer and dies that include one or more contacts using nitridized molybdenum in accordance with any of the embodiments of the present disclosure.

FIG. 8 is a cross-sectional side view of an IC package that may include one or more IC devices with contacts using nitridized molybdenum in accordance with any of the embodiments of the present disclosure.

FIG. 9 is a cross-sectional side view of an IC device assembly that may include one or more IC devices with contacts using nitridized molybdenum in accordance with any of the embodiments of the present disclosure.

FIG. 10 is a block diagram of an example computing device that may include one or more IC devices with contacts using nitridized molybdenum in accordance with any of the embodiments of the present disclosure.

FIG. 11 is a block diagram of an example radio frequency (RF) device that may include one or more IC devices with contacts using nitridized molybdenum in accordance with any of the embodiments of the present disclosure.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

In integrated circuit (IC) devices, contacts (or electrodes) are the metal components that are in contact with a semiconductor material of IC components such as transistors, diodes, capacitors, or other IC components. The contacts may provide an electrical path for current to flow in and/or out of a respective IC component. Currently, titanium is widely used as a contact metal in N-type metal-oxide-semiconductor (NMOS) transistors and P-type metal-oxide-semiconductor (PMOS) transistors. To that end, titanium may be deposited on NMOS and/or PMOS transistors, followed by various fabrication steps including, but not limited to, ex-situ silicide annealing, etching, and contact metal fill to form transistor contacts.

One issue is that the fabrication steps (e.g., from contact deposition to contact metal fill) for forming contacts in an IC device may cause the contact metals (e.g., titanium) to be oxidized. Oxidation can degrade the resistivity of the contact, and thus may impact the electrical performance (e.g., conductivity) of the device. One approach to protecting the titanium from oxidation is to diffuse nitrogen into a surface of the titanium deposit, for example, using a physical vapor deposition (PVD) process or a chemical vapor deposition (CVD) process to form a layer (e.g., a thin film) of titanium nitride before a contact metal fill step. However, the PVD or CVD deposited titanium nitride may not be a good barrier for oxygen and/or fluorine (e.g., coming from a subsequent tungsten (W) deposition fill step), leading to a lower contact performance. Accordingly, there is a need to improve contact performance.

Recently, molybdenum has gained interest in many applications due to its desirable properties. For instance, molybdenum may provide good conductivity, high stability at high temperatures, and/or a high stability in terms of reaction to oxide. In particular, molybdenum may be more conductive than titanium. Accordingly, it may be desirable to utilize molybdenum in forming contacts for IC devices. However, molybdenum can have dangling bonds that react with oxygen, thus still leading to the above-described problems associated with contact oxidation.

Accordingly, the present disclosure provides methods, devices, and systems for forming contacts in IC devices using molybdenum in a way that allows benefiting from the desirable properties of molybdenum while reducing the oxidation challenges described above. In one embodiment, molybdenum may be used in place of titanium for forming contacts in IC devices. In another embodiment, molybdenum may be deposited over titanium for forming contacts in IC devices. In either one of these embodiments, to prevent the molybdenum from being oxidized during the formation (e.g., silicide annealing and contact metal fill) of the contacts, a nitridization process may be applied to the molybdenum. Nitridization (or nitriding) is a process in which nitrogen is introduced (or diffused) into the surface of a material. As a result of the nitriding process, at least some of the dangling bonds of the molybdenum may react with (e.g., connect to) nitrogen, advantageously reducing the number of dangling bonds available to react with oxygen. The present disclosure may use the terms “contact” and “electrode” interchangeably to refer to a metal component in contact with a semiconductor material in an IC device.

According to embodiments of the present disclosure, an IC device may include a semiconductor material and a contact (e.g., an electrically conductive contact). The contact may include molybdenum and may extend to a portion of the semiconductor material. The contact may also include nitrogen. For example, the contact may include the molybdenum in a first layer and a second layer, where the second layer may further include the nitrogen. The second layer may correspond to a layer of the molybdenum being nitridized, forming nitridized molybdenum. In some instances, it may be desirable for the molybdenum to be in a thick layer, for example, to support contact metal fill. In an example, the first layer (of molybdenum) may have a thickness between about 5 and 16 nanometers, and the second layer (of nitridized molybdenum) may have a thickness between about 1 and 2 nanometers. Further, an atomic density of the molybdenum in the first layer may be at least about 80%, an atomic density of the molybdenum in the second layer may be at least about 60%, and an atomic density of the nitrogen in the second layer may be at least about 20%.

In some embodiments, the contact may further include a fill material (e.g., a first electrically conductive material), and the IC device may further include an insulating material, where the contact may be in an opening of the insulating material. As discussed above, titanium is commonly used for contacts in IC devices. In one embodiment, the contact may be formed using molybdenum in place of titanium. In this regard, the first layer of molybdenum may be on at least sidewalls of the opening and may be between the insulating material and the fill material, and the second layer of nitridized molybdenum may be a thin film on top of the first layer of molybdenum. In some examples, the second layer of nitridized molybdenum may be in contact with the fill material. In another embodiment, the contact may be formed using molybdenum and a second electrically conductive material (e.g., titanium). For instance, the second electrically conductive material may be on at least sidewalls of the opening, and the first layer (of molybdenum) and the second layer (of nitridized molybdenum) may be between the second electrically conductive material and the first electrically conductive material.

In some embodiments, the semiconductor material may be doped, for example, including an N-type dopants or a P-type dopants. In some embodiments, the semiconductor material over which the contact is formed may have a shape of a fin. In some embodiments, the IC device may include a transistor, where the semiconductor material and the contact may be part of the transistor. For instance, the semiconductor material and the contact may correspond to a source region and a source contact or electrode of the transistor, respectively. Alternatively, the semiconductor material and the contact may correspond to a drain region and a drain contact or electrode of the transistor, respectively. In general, the present disclosure may be suitable for use in forming contacts for any suitable components (e.g., transistors, diodes, capacitors, etc.).

Each of the structures, packages, methods, devices, and systems of the present disclosure may have several innovative aspects, no single one of which being solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc. Similarly, the terms naming various compounds refer to materials having any combination of the individual elements within a compound (e.g., “gallium arsenide” or “GaAs” may refer to a material that includes Gallium and Arsenic). Further, the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value based on the context of a particular value as described herein or as known in the art.

The term “interconnect” may refer to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The terms such as “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

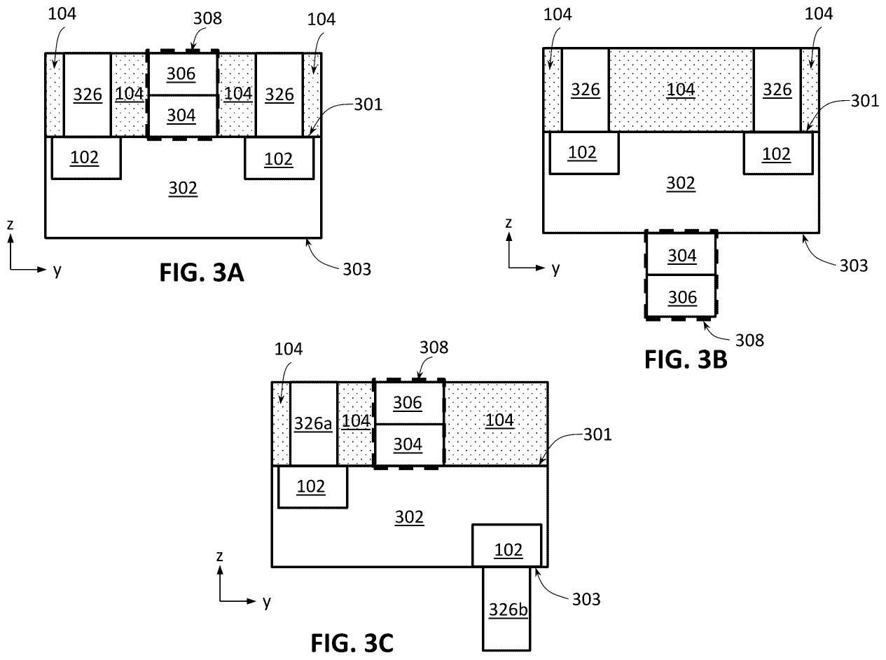

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 3A-3C, such a collection may be referred to herein without the letters, e.g., as “FIG. 3.” In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

In the drawings, some schematic illustrations of example structures of various structures, devices, and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with contacts using nitridized molybdenum as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with contacts using nitridized molybdenum as described herein may be implemented in one or more components associated with an IC or/and between various such components. In various embodiments, components associated with an IC include, for example, transistors, diodes, power sources, resistors, capacitors, inductors, sensors, transceivers, transmitters, receivers, antennas, etc. Components associated with an IC may include those that are mounted on an IC, provided as an integral part of an IC, or those connected to an IC. The IC may be either analog or digital, or may include a combination of analog and digital circuitry, and may be used in a number of applications, such as microprocessors, optoelectronics, logic blocks, audio amplifiers, etc., depending on the components associated with the IC. In some embodiments, IC devices with contacts using nitridized molybdenum as described herein may be included in a RFIC, which may, e.g., be included in any component associated with an IC of an RF receiver, an RF transmitter, or an RF transceiver, or any other RF device, e.g., as used in telecommunications within base stations (BS) or user equipment (UE) devices. Such components may include, but are not limited to, power amplifiers, RF switches, RF filters (including arrays of RF filters, or RF filter banks), or impedance tuners. In some embodiments, the IC devices with contacts using nitridized molybdenum as described herein may be employed as part of a chipset for executing one or more related functions in a computer.

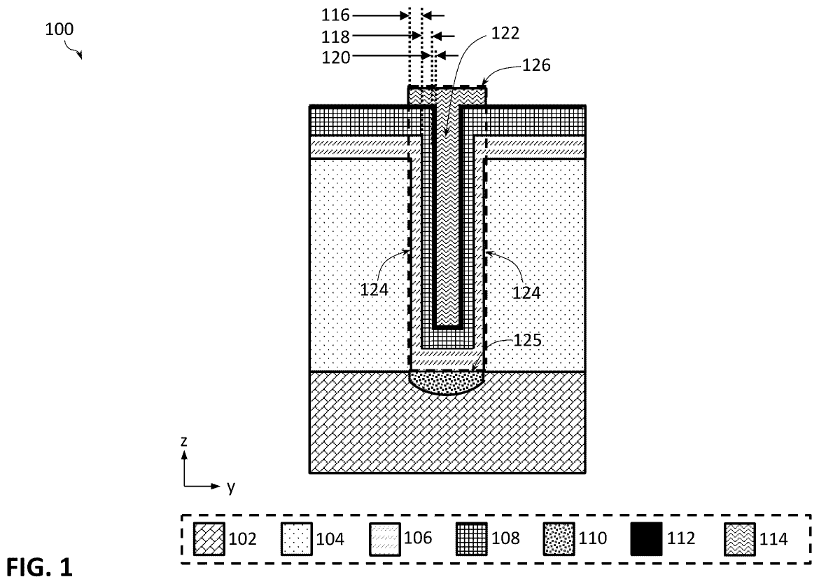

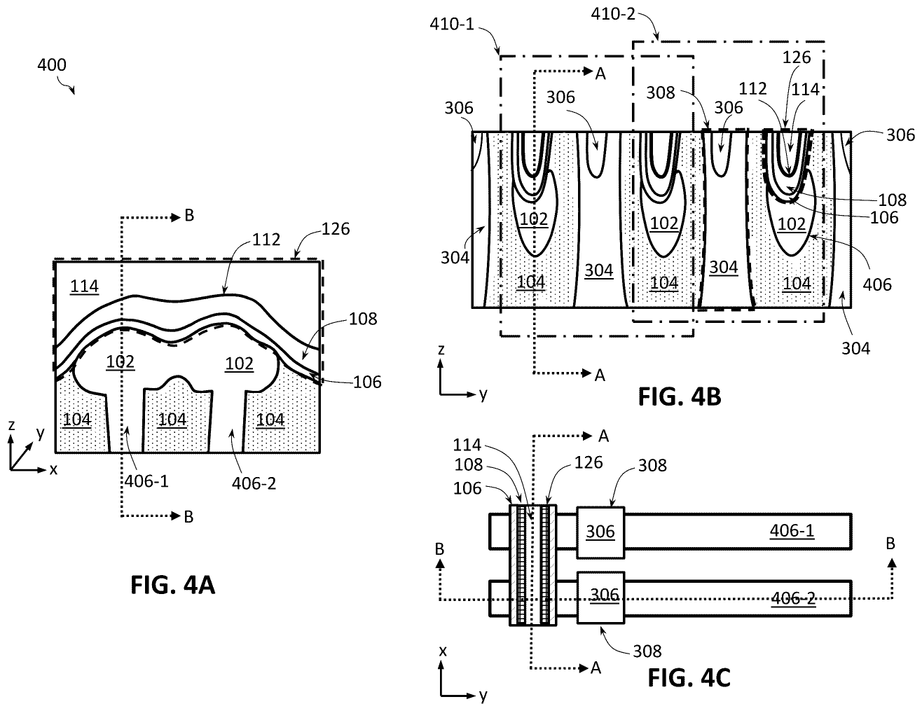

FIG. 1 is a cross-sectional side view of an example contact arrangement 100 with nitridized molybdenum, according to various embodiments of the present disclosure. A legend provided within a dashed box at the bottom of FIG. 1 illustrates colors/patterns used to indicate some of the elements of the contact arrangement 100 so that FIG. 1 is not cluttered by too many reference numerals. For example, FIG. 1 uses different colors/patterns to illustrate a semiconductor material 102, an insulating material 104, molybdenum 108, a first electrically conductive material 114, a second electrically conductive material 106, a third electrically conductive material 110, and molybdenum nitride 112, etc. In some examples, the contact arrangement 100 may be part of an IC device, and the cross-sectional side view may correspond to a longitudinal side view of the IC device, e.g., a cross section taken along a y-z plane of the IC device 400 of FIGS. 4A-4C in a reference coordinate system x-y-z shown in FIG. 4A.

As shown in FIG. 1, the contact arrangement 100 may include a semiconductor material 102 and an insulating material 104 disposed cover the semiconductor material 102. The insulating material 104 may include an opening 122. The contact arrangement 100 may further include a contact 126 (shown by the dash-lined shape) in the opening 122. The contact 126 may extend through the opening 122 into a portion of the semiconductor material 102.

The contact 126 may include molybdenum (Mo) 108, molybdenum nitride (MoNx) 112, a first electrically conductive material 114, and a second electrically conductive material 106. In this regard, the second electrically conductive material 106 may be disposed on (or extend along) sidewalls 124 of the opening 122. In some instances, the second electrically conductive material 106 may also be at a bottom 125 of the opening 122 as shown in FIG. 1. For instance, the opening 122 may expose a portion of the semiconductor material 102. As such, a portion of the second electrically conductive material 106 may be introduced (e.g., diffused) into a portion of the semiconductor material 102 near the opening 122 during the deposition of the second electrically conductive material, forming a third electrically conductive material 110 near the opening 122 and/or the bottom of the contact 126.

The molybdenum 108 may be in a layer on top of the second electrically conductive material 106. The molybdenum nitride 122 may be in a layer (a thin film layer) on top of the layer of molybdenum 108. The first electrically conductive material 114 may be a fill material that fills the remaining portion of the opening 122. Accordingly, the layer of molybdenum 108 and the layer of molybdenum nitride 112 may be between the first electrically conductive material 114 and the second electrically conductive material 106, and the layer of molybdenum nitride 112 may be between the layer of molybdenum 108 and the first electrically conductive material 114. In some examples, the layer of molybdenum nitride 112 may be in direct contact with the first electrically conductive material 114.

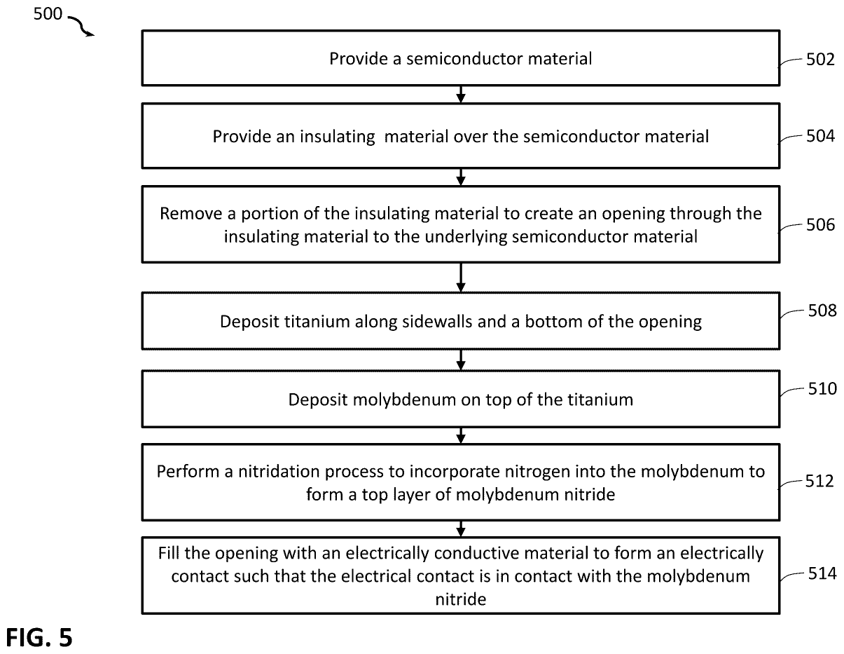

As will be discussed more fully below with reference to FIG. 5, the contact 126 may be formed by depositing the molybdenum 108, followed by a nitridization process to introduce nitrogen into a top surface of the molybdenum to form the molybdenum nitride 112. The nitridized molybdenum is a dense and low stress film that can protect the underlying second electrically conductive material 106 and the molybdenum 108 from oxidation during subsequent fabrication steps. In general, the molybdenum nitride 112 may be a refractory material with a low resistance and low oxygen permeation. Accordingly, the contact arrangement 100 may advantageously provide a lower contact resistance (or a higher conductance) compared to contacts formed from titanium without molybdenum.

In some embodiments, the layer of the second electrically conductive material 106 (along the sidewalls 124) may have a thickness 116 (a dimension in the direction of the y-axis) between about 2 nanometers and 9 nanometers (e.g., between about 3 and 8 nanometers, between about 4 and 7 nanometers, or about 6 nanometers). In some embodiments, it may be desirable for the molybdenum 108 to have a certain thickness to support the filling of the first conductive material 114. For instance, the layer of molybdenum 108 may have a thickness 118 (a dimension in the direction of the y-axis) between about 5 and 11 nanometers (e.g., between about 6 and 10 nanometers or between about 7 and 9 nanometers). The layer of molybdenum nitride 112 may be a thin film, for example, having a thickness 120 (a dimension in the direction of the y-axis) between about 0.5 and 2.5 nanometers (e.g., between about 1 and 2 nanometers). In some further embodiments, the thickness of each of the layer of the second electrically conductive material 106 and the layer of molybdenum 108 in the direction of the z-axis may be greater than the thickness of the respective layer in the direction of the y-axis. For instance, the thickness 118 of the layer of molybdenum 108 in the y-direction may be about one-third of the thickness of the layer of molybdenum 108 in the z-direction. Further, the thickness of each of the layer of the second electrically conductive material 106 and the layer of molybdenum 108 may be substantially uniform along the sidewalls 124 of the opening 122.

In some embodiments, an atomic percentage of molybdenum 108 in the layer is at least about 80% (e.g., between about 80% and 100%, between about 90% and 100% or between about 95% and 100%). In some embodiments, an atomic percentage of nitrogen in the layer of the molybdenum nitride 112 is at least about 20% (e.g., between about 20% and 40% or between 25% and 35%). In some embodiments, an atomic percentage of molybdenum in the layer of molybdenum nitride 112 is at least about 60% (e.g., between about 60% and 80% or between about 65% and 75%).

The contact arrangement 100 may be part of an IC device. More specifically, the contact 126 may be an example of a contact of a component within an IC device. In an example, the contact 126 may correspond to one of a source electrode or a drain electrode of a transistor, and the semiconductor material 102 may correspond to a respective source or drain region. The contact arrangement 100 may generally be used to provide contacts in transistors of any suitable architectures, for example, as shown in FIGS. 3A-3C. Further, the contact arrangement 100 may be used to provide contacts in planar transistors or a non-planar transistors, such as fin-based field effect transistors (finFET), nanoribbon transistors, nanowire transistors, and so on. In another example, the contact 126 may correspond to an electrode (e.g., one of an anode or a cathode) of a diode, and the semiconductor material 102 may correspond to a doped region that forms part of a PN junction of the diode. In general, the contact 126 may be electrically coupled to the semiconductor material 102 to provide an electrical path for current to flow in and/or out of a respective component, and the semiconductor material 102 may be three-dimensional (3D) (e.g., in the shape of a fin, an elongated ribbon, etc.) or two-dimensional (2D).

In general, the semiconductor material 102 may be composed of semiconductor material systems including, for example, N-type or P-type materials systems. In some embodiments, the semiconductor material 102 may include a high mobility oxide semiconductor material, such as tin oxide, antimony oxide, indium oxide, indium tin oxide, titanium oxide, zinc oxide, indium zinc oxide, indium gallium zinc oxide, gallium oxide, titanium oxynitride, ruthenium oxide, or tungsten oxide. In general, the semiconductor material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

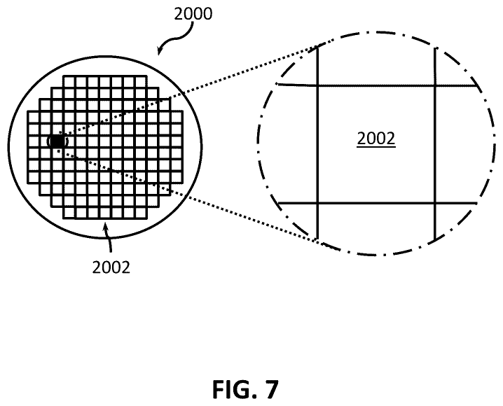

In some embodiments, the semiconductor material 102 may be a doped semiconductor material. For instance, dopants such as boron, aluminum, antimony, phosphorous, or arsenic may be ion-implanted into the semiconductor material 102. Alternatively, the semiconductor material may be epitaxially grown on a semiconductor support structure or substrate (e.g., the wafer 2000 of FIG. 7). In some implementations, the semiconductor material 102 may include silicon alloy such as silicon germanium or silicon carbide. In some implementations the epitaxially deposited silicon alloy may be doped in situ with dopants such as boron, arsenic, or phosphorous. In further embodiments, the semiconductor material 102 may include one or more alternate semiconductor materials such as germanium or a group III-V material or alloy. And in further embodiments, the semiconductor material 102 may include one or more layers of metal and/or metal alloys. In other embodiments, the semiconductor material 102 may include a semiconductor material that is not deliberately doped.

In general, the insulating material 104 may be an isolation layer that electrically isolates the contact 126 from another circuit element (e.g., another electrode or contact which may or may not be the same as the contact 126) in an IC device. In some embodiments, the insulating material 104 may include any suitable interlayer dielectric (ILD) material such as any suitable interlayer dielectric (ILD) material. In some embodiments, such an insulator material 104 may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material 104 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

In certain embodiments, the second electrically conductive material 106 on the sidewalls 124 and the bottom 125 of the opening 122 may include titanium. Accordingly, the third conductive material 110 near the opening 122 and/or near a bottom portion of the contact 126 may include titanium silicide (TiSi) when the semiconductor material 102 includes silicon, for example. In certain embodiments, the first electrically conductive material 114 (the fill material) of the contact 126 may include tungsten. In general, the first electrically conductive material 114 (the fill material) may include any suitable electrically conductive material, alloy, or a stack of multiple electrically conductive materials. In some embodiments, the fill material may include one or more metals or metal alloys, with metals e.g., copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the fill material may include one or more electrically conductive alloys, oxides, or carbides of one or more metals.

Implementations of the present disclosure may be formed or carried out on any suitable support structure, such as a substrate, a die, a wafer, or a chip. In particular, the contact arrangement 100 may be provided over any suitable support structure. Such a support structure is not shown in FIG. 1. The support structure may, e.g., be the wafer 2000 of FIG. 7, discussed below, and may be, or be included in, a die, e.g., the singulated die 2002 of FIG. 7, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the support structure may be formed are described here, any material that may serve as a foundation upon which an IC device implementing one or more contacts using nitridized molybdenum as described herein may be built falls within the spirit and scope of the present disclosure.

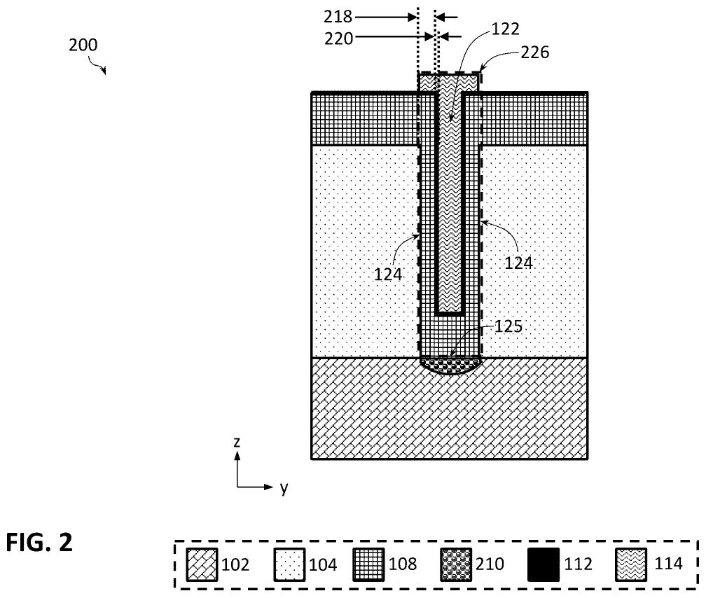

FIG. 2 is a cross-sectional side view of an example contact arrangement 200 with nitridized molybdenum, according to various embodiments of the present disclosure. Similar to FIG. 1, a legend provided within a dashed box at the bottom of FIG. 2 illustrates colors/patterns used to indicate some of the elements of the contact arrangement 200 so that FIG. 2 is not cluttered by too many reference numerals. Further, for simplicity, FIG. 2 may use the reference numerals as in FIG. 1 to refer to the same materials and/or structures as in FIG. 1. In some examples, the contact arrangement 200 may be part of an IC device, and the cross-sectional side view may correspond to a longitudinal side view of the IC device, e.g., a cross section taken along an y-z plane of the IC device 400 of FIGS. 4A-4C in a reference coordinate system x-y-z.

As shown in FIG. 2, the contact arrangement 200 of FIG. 2 may be similar to the contact arrangement 100 of FIG. 1 in many respects. For example, the contact arrangement 200 may include a semiconductor material 102, an insulating material 104 disposed over the semiconductor material 102, and a contact 226 in the opening 122 of the insulating material 104, for example, extending through the opening 122 into a portion of the semiconductor material 102. In contrast to the contact arrangement 100, the contact 126 may include molybdenum 108, molybdenum nitride 112, and the first electrically conductive material 114 but not the second electrically conductive material 106. As shown, the molybdenum 108 may be disposed on the sidewalls 124 of the opening 122 and at the bottom 125 of the opening 122 and may be between the insulating material 104 and the fill material (the first electrically conductive material 114). Further, the layer of molybdenum nitride 112 may be between the layer of molybdenum 108 and the first electrically conductive material 114 (the fill material). In some examples, the layer of molybdenum nitride 112 may be in direct contact with the first electrically conductive material 114. Further, as discussed above, the opening 122 may expose a portion of the semiconductor material 102. As such, a portion of the molybdenum 108 may be introduced (e.g., diffused) into a portion of the semiconductor material 102 near the opening 122 during the deposition of the molybdenum 108, forming a fourth electrically conductive material 210 near the opening 122 and/or the bottom of the contact 226.

As explained above, in some embodiments, it may be desirable for the molybdenum 108 to have a certain thickness to support the filling of the first conductive material 114. For instance, the layer of molybdenum 108 may have a thickness 218 (a dimension in the direction of the y-axis) between about 9 and 16 nanometers (e.g., between about 10 and 15 nanometers or between about 9 and 14 nanometers). Similar to the contact 126, the layer of molybdenum nitride 112 may be a thin film, for example, having a thickness 220 (a dimension in the direction of the y-axis) between about 0.5 and 2.5 nanometers (e.g., between about 1 and 2 nanometers). In some further embodiments, the thickness of the layer of molybdenum 108 in the direction of the z-axis may be greater than the thickness of the layer of molybdenum 108 in the direction of the y-axis. For instance, the thickness 218 of the layer of molybdenum 108 in the y-direction may be about one-third of the thickness of the layer of molybdenum 108 in the z-direction.

Similar to the contact arrangement 100 of FIG. 1, in some embodiments, an atomic percentage of molybdenum 108 in the layer is at least about 80% (e.g., between about 80% and 100%, between about 90% and 100% or between about 95% and 100%). In some embodiments, an atomic percentage of nitrogen in the layer of the molybdenum nitride 112 is at least about 20% (e.g., between about 20% and 40% or between 25% and 35%). In some embodiments, an atomic percentage of molybdenum in the layer of molybdenum nitride 112 may be at least about 60% (e.g., between about 60% and 80% or between about 65% and 75%).

Similar to the contact arrangement 100 of FIG. 1, the contact arrangement 200 of FIG. 2 may be part of an IC device. For instance, the contact 226 may be an example of a contact or electrode of a transistor, a diode, or any suitable devices. Further, the contact arrangement 200 of FIG. 2 may be provided over a support structure as discussed above and further below.

In general, contacts formed from nitridized molybdenum as discussed herein may provide an improved electrical performance (e.g., a lower resistance or a higher conductivity) compared to contacts formed using titanium or titanium nitride. The nitridized molybdenum may act as a hermetic capping layer for the contacts 126 and 226 discussed above to protect the contacts 126 and 226 from oxidation during the fabrication process (e.g., silicide annealing and contact metal fill).

In some embodiments, the contact arrangement 100 of FIG. 1 (with the contact 126 including titanium as the second electrically conductive material, the molybdenum 108, and the molybdenum nitride 112) may be suitable for use in an NMOS transistor or a PMOS transistor. For instance, the semiconductor material 102 in the contact arrangement 100 of FIG. 1 may include silicon doped with N-type dopants, where the semiconductor material 102 and the contact 126 may respectively correspond to an S/D region and an S/D contact or electrode in an NMOS transistor, a PMOS transistor, a complementary metal-oxide-semiconductor (CMOS) transistor. In some embodiments, the contact arrangement 200 of FIG. 2 (where the contact 126 includes the molybdenum 108 and the molybdenum nitride 112) may be suitable for use in a PMOS transistor but not in a NMOS transistor. For instance, the semiconductor material 102 in the contact arrangement 200 of FIG. 2 may include silicon doped with P-type dopants, where the semiconductor material 102 and the contact 126 may respectively correspond to an S/D region and an S/D contact or electrode in a PMOS transistor.

In general, the contact arrangement 100 of FIG. 1 and the contact arrangement 200 of FIG. 2 as described above may be included in any suitable transistor structure. For example, FIGS. 3A-3C provide cross-sectional side views of example transistors having S/D contacts (or electrodes) with nitridized molybdenum, according to various embodiments of the present disclosure. Applicable to all embodiments of the transistor structures shown in FIG. 3, the transistor structures include S/D electrodes 326, each including molybdenum 108 and molybdenum nitride 112 as shown in any of FIGS. 1 and 2. Thus, any of the S/D electrodes 326 of the transistors 300 discussed below with reference to FIG. 3 may take the form of any of the embodiments of those components discussed above with reference to FIGS. 1 and 2, which descriptions, therefore, are not repeated here in the interests of brevity. Also, applicable to all embodiments of the transistor structures shown in FIG. 3, the transistor structures may further include a channel material 302, a semiconductor material 102 (e.g., S/D regions), an insulating material 104, a gate dielectric 304, and a gate electrode 306.

The transistors 300 illustrated in FIG. 3 do not represent an exhaustive set of transistor structures in which S/D electrodes 326 with nitridized molybdenum may be included, but that may provide examples of such structures. For example, in other embodiments, any of the S/D electrodes 326 with nitridized molybdenum described herein may be used in transistors implementing tri-gate or all-around gate architectures. In another example, the gate stack 308 may be at least partially recessed into the channel material 302, as known in the art. FIG. 3 is intended to show relative arrangements of the components therein, and, in various further embodiments, transistors 300 may include other components that are not illustrated (e.g., conductive pathways to the source, drain, and gate electrodes, etc.). Furthermore, the transistors 300 illustrated in FIG. 3 may further include other components not specifically shown, e.g., in order to not clutter the drawings or because there are many different ways to implement such other components.

The channel material 302 may be composed of semiconductor material systems including, for example, N-type or P-type materials systems. In some embodiments, the channel material 302 may include a high mobility oxide semiconductor material, such as tin oxide, antimony oxide, indium oxide, indium tin oxide, titanium oxide, zinc oxide, indium zinc oxide, indium gallium zinc oxide, gallium oxide, titanium oxynitride, ruthenium oxide, or tungsten oxide. In general, the channel material 302 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material 302 may have a thickness between about 5 and 30 nanometers, including all values and ranges therein.

The gate dielectric 304 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 304 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 304 during manufacture of the transistors 300 to improve the quality of the gate dielectric 304. In some embodiments, the gate dielectric 304 may have a thickness between about 0.5 nanometers and 3 nanometers, including all values and ranges therein, e.g., between about 1 and 3 nanometers, or between about 1 and 2 nanometers.

In some embodiments, the gate dielectric 304 may be a multilayer gate dielectric, e.g., it may include any of the high-k dielectric materials in one layer and a layer of IGZO. In some embodiments, the gate stack (i.e., a combination of the gate dielectric 304 and the gate electrode 306) may be arranged so that the IGZO is disposed between the high-k dielectric and the channel material 302. In such embodiments, the IGZO may be in contact with the channel material 302 and may provide the interface between the channel material 302 and the remainder of the multilayer gate dielectric 304. The IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10).

The gate electrode 306 may include at least one P-type work function metal or N-type work function metal, depending on whether the S/D electrodes 326 are to be included in a PMOS transistor or an NMOS transistor. For a PMOS transistor, metals that may be used for the gate electrode 306 may include, but are not limited to, ruthenium, palladium, platinum, cobalt, nickel, and conductive metal oxides (e.g., ruthenium oxide). For an NMOS transistor, metals that may be used for the gate electrode 306 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 306 may consist of a stack of two or more metal layers, where one or more metal layers are work function metal layers and at least one metal layer is a fill metal layer. Further metal layers may be included for other purposes, such as to act as a barrier layer.

FIG. 3A depicts a transistor 300A having a “top” gate provided by a gate stack 308 of the gate electrode 306 and the gate dielectric 304, illustrating an embodiment of a top-gate transistor in which S/D electrodes 326 with nitridized molybdenum as described herein may be used. As shown in FIG. 3A, the gate dielectric 304 may be disposed between the gate electrode 306 and the channel material 302. While not shown, the channel material 302 may be provided over a support structure or substrate, e.g., the channel material 302 may be in contact with the substrate. The transistor 300A may include S/D electrodes 326 and the gate stack 308 may be on the same side 301 (e.g., a top side) of the channel material 302. Further, the S/D electrodes 326 and the gate stack 308 may be spaced apart from each other by the insulating material 104, and the gate stack 308 may be between the S/D electrodes 326. In the embodiment of FIG. 3A, at least some portions of the S/D electrodes 326 and the gate stack 308 may be coplanar with at least some portions of the channel material 302.

In some embodiments, the channel material 302 may be three-dimensional and may be in the shape of a fin. For instance, the transistor 300A may be a finFET. In other embodiments, the channel material 302 may be two-dimensional. For instance, the transistor 300A may be a planar transistor.

FIG. 3B depicts a transistor 300B having a “bottom” gate provided by a gate stack 308 of the gate electrode 306 and the gate dielectric 304, illustrating an embodiment of a bottom-gate transistor in which S/D electrodes 326 with nitridized molybdenum as described herein may be used. In contrast to the transistor 300A of FIG. 3A, the transistor 300B may include S/D electrodes 326 and a gate stack 308 on different sides of the channel material 302. More specifically, the S/D electrodes may be disposed on one side 301 (e.g., a top side) of the channel material 302 while the gate stack 308 of the gate electrode 306 and the gate dielectric 304 may be disposed on an opposite side 303 (e.g., a bottom side) of the channel material 302. Further, the S/D electrodes 326 may be spaced apart from each other by an insulating material 104, and the gate stack 308 may be between the S/D electrodes 326 in the direction of the y-axis.

In some embodiments, the channel material 302 may be three-dimensional and may be in the shape of a nanowire or nanoribbon. For instance, the transistor 300B may be a nanowire/nanoribbon transistor. In other embodiments, the channel material 302 may be two-dimensional. For instance, the transistor 300B may be a planar transistor.

FIG. 3C depicts a transistor 300C having a source electrode and a drain electrode on opposite sides of a channel material 302, illustrating an embodiment of a transistor in which S/D electrodes with nitridized molybdenum as described herein may be used. In contrast to the transistor 300A of FIG. 3A, the transistor 300B may include S/D electrodes 326 on different sides of the channel material 302. More specifically, one of the S/D electrodes 326 (show as 326a) may be spaced apart from a gate stack 308 by an insulating material 104 and disposed on the same side 301 as the gate stack 308 while the other S/D electrodes 326 (shown as 326b) may be disposed on an opposite side 303 (e.g., a bottom side) of the channel material 302.

In various embodiments, an IC device may include a transistor including source and/or drain electrodes as discussed above with reference to FIGS. 1 and 2 and may have a transistor architecture as discussed above with reference to FIGS. 3A-3C. For example, an IC device may include a transistor including a semiconductor material (e.g., the semiconductor material 102), a source electrode, and a drain electrode, where at least one of the source electrode or the drain electrode (e.g., the contact 126 or 226, the S/D electrodes 326) includes molybdenum. The transistor may further include an insulating material (e.g., the insulating material 104). The at least one of the source electrode or the drain electrode may further include a fill material (e.g., electrically conductive material such as the first electrically material 114). The at least one of the source electrode or the drain electrode may be in an opening (e.g., the opening 122) of the insulating material. The molybdenum may be in a first layer and a second layer, and the second layer may further include nitrogen. The second layer may be between the first layer and the fill material and in contact with the fill material.

In some embodiments of the IC device, the first layer (of molybdenum) may be at least on sidewalls (and possibly also at the bottom) of the opening and may be between the insulating material and the fill material, for example, as discussed above with reference to FIG. 2.

In some embodiments of the IC device, the electrically conductive material may be a first electrically conductive material. The at least one of the source electrode or the drain electrode may further include a second electrically conductive material (e.g., titanium), where the second electrically conductive material may be at least on sidewalls (and possibly also at the bottom) of the opening. The first layer (of molybdenum) may be between the first electrically conductive material and the second electrically conductive material, for example, as discussed above with reference to FIG. 1.

In some embodiments of the IC device, the transistor may further include a channel material and a gate electrode, and the semiconductor material may be at least partially enclosed within the channel material. Further, in one embodiment, the at least one of the source electrode or the drain electrode and the gate electrode may be on one side of the channel material, for example, as discussed above with reference to FIG. 3A. In another embodiment, the one of the source electrode or the drain electrode may be on one side of the channel material while the gate electrode may be on another side of the channel material, for example, as discussed above with reference to FIG. 3B. In yet another embodiment, the source electrode may be on one side of the channel material while the drain electrode may be on another side of the channel material, for example, as discussed above with reference to FIG. 3C.

FIGS. 4A-4C are a cross-sectional side views of an example IC device 400 having contacts with nitridized molybdenum, according to various embodiments of the present disclosure. In an embodiment, the device 400 shown in FIG. 4 may be a fin-based transistor device, where semiconductor materials in the device 400 may be in the shape of a fin. In the illustrated example of FIG. 4, the fin-based transistor device 400 may have S/D electrodes utilizing the contact arrangement 100 as discussed above with reference to FIG. 1. However, in other examples, the fin-based transistor device 400 may have S/D electrodes utilizing the contact arrangement 200 as discussed above with reference to FIG. 2. Further, in general, the fin-based device 400 may include any suitable number of fins (e.g., 1, 2, 3, 4, 5 or more). For simplicity, FIG. 4 may use the reference numerals in FIGS. 1, 2, and/or 3 to refer to the same materials or same structures as in FIGS. 1, 2, and/or 3.

FIG. 4A is an example cross section of the device 400 along the plane AA shown in FIGS. 4B and 4C. FIG. 4B is an example cross section of the device 400 along the plane BB shown in FIGS. 4A and 4C. The plane AA may correspond to an x-z plane in a reference coordinate system x-y-z. The plane BB may correspond to a y-z plane. FIG. 4C is an example top view of the device 400 shown in FIG. 4B, where the top view may be in an x-y plane.

Turning to FIG. 4A, the cross section of the device 400 illustrates the device 400 having two fins 406 (individually shown as 406-1 and 406-2). The fins 406 may extend in a direction of the y-axis. The fins 406 may include a semiconductor material. In particular, an upper portion of the fins 406 may include a semiconductor material 102 doped with P-type dopant or N-type dopants. A lower portion of the fins 406 may be spaced apart from each other by an insulating material 104. The doped semiconductor material 102 in each of the fins 406 may correspond to a source region or a drain region for transistor(s) in the device 400, for example, epitaxially grown as will be discussed further below with reference to FIG. 5. As shown in FIG. 4A, the device 400 may further include a contact 126. The contact 126 may include a second electrically conductive material 106 (e.g., including titanium) and molybdenum 108 over the second electrically conductive material 106, where a top layer of the molybdenum 108 may be nitridized to form a thin film or layer of molybdenum nitride 112 as discussed herein. The contact 126 may further include a fill material (e.g., a first electrically conductive material 114), where the layer of molybdenum nitride 112 may be in contact with the fill material.

Turning to FIG. 4B, the cross section of the device 400 in the y-z plane illustrate the device 400 including S/D contacts 126 (only one of which is labeled with a reference numeral in FIG. 4B in order not to clutter the drawings). As shown, the device 400 may include multiple S/D contacts 126 and respective S/D regions formed from the semiconductor material 102. The device 400 may include gate stacks 308, each including a gate dielectric 304 and a gate electrode 306. The S/D contacts 126 may be spaced apart from each other by one of the gate stacks 308. Further, the device 400 may include an insulating material 104 that separates the gate stacks 308 from the S/D contacts 126 and respective S/D regions. In an example, a transistor 410-1 or 410-2 may be formed from a nearest-neighbor pair of S/D contacts 126 and respective S/D regions (e.g., the semiconductor material 102) and a respective gate stack 308 therebetween. In an example, two adjacent transistors 410-1 and 410-2 in the device 400 may share the same S/D contact 126. In other examples, different transistors may not share the same S/D contacts.

Turning to FIG. 4C, the top view of the device 400 may include the two fins 406-1 and 406-2. In order not to clutter the drawings in FIG. 4C, only one S/D contact 126 and one gate stack 308 is illustrated in FIG. 4C. As shown, a top view of the S/D contact 126 may include the second electrically conductive material 106 (e.g., titanium), the molybdenum 108, the molybdenum nitride 112 on the side and with the fill material (e.g., the first electrically conductive material 114) in the middle. As further shown, a top view of the gate stack 308 may include the gate electrode 306. While FIG. 4 illustrates the device 400 including an S/D contact 126 extending across the two fins 406-1 and 406-2, in other examples, an S/D contact 126 may be on only one fin 406-1 or 406-2. Further, while FIG. 4 illustrate the device 400 including a gate stack 308 on each fin 406-1 or 406-2, in other examples, a gate stack 308 may extend across the two fins 406-1 and 406-2. In general, the gate stack 308 and the S/D contacts 126 (including molybdenum 108 and molybdenum nitride 112 as discussed herein) may be arranged in any suitable configurations to provide various transistor architectures.

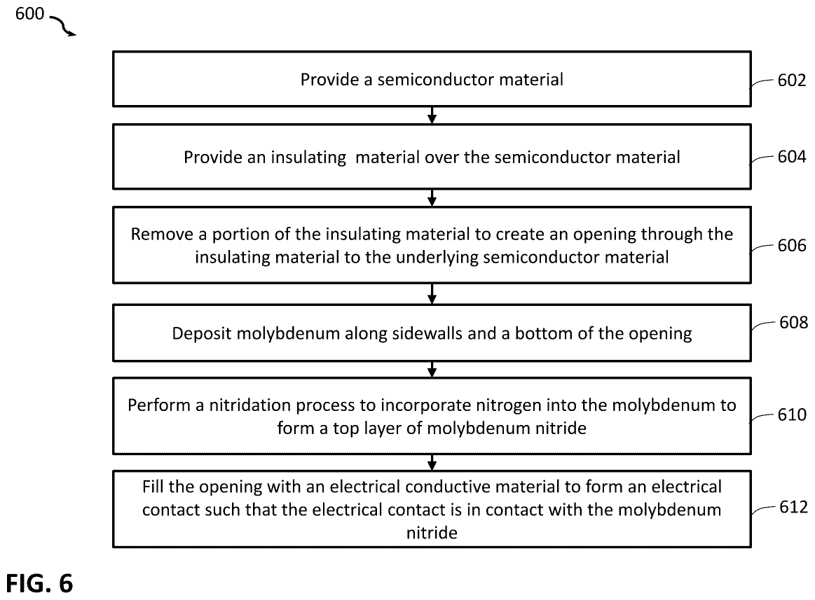

FIG. 5 and FIG. 6 provide flow diagrams of, respectively, an example method 500 and an example method 600 of manufacturing an IC device with contacts using nitridized molybdenum, according to some embodiments of the disclosure. The method 500 may be utilized to form the contact arrangement 100 of FIG. 1, while the method 600 may be utilized to form the contact arrangement 200 of FIG. 2. Although the operations of the methods 500, 600 are illustrated once each and in a particular order, the operations may be performed in any suitable order and repeated as desired. For example, one or more operations may be performed in parallel to manufacture, substantially simultaneously, electrodes or contacts as described herein. In another example, the operations may be performed in a different order to reflect the structure of a particular device assembly in which one or more electrodes or contacts as described herein will be included.

In addition, the example manufacturing methods 500, 600 may include other operations not specifically shown in FIGS. 5, 6, such as various cleaning or planarization operations as known in the art. For example, in some embodiments, a support structure (e.g., the wafer 2000 of FIG. 7), as well as layers of various other materials subsequently deposited thereon, may be cleaned prior to, after, or during any of the processes of the methods 500, 600 described herein, e.g., to remove oxides, surface-bound organic and metallic contaminants, as well as subsurface contamination. In some embodiments, cleaning may be carried out using e.g., chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the diodes structures/assemblies described herein may be planarized prior to, after, or during any of the processes of the methods 500, 600 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

In various embodiments, any of the processes of the methods 500, 600 may include any suitable patterning techniques, such as photolithographic or electron-beam (e-beam) patterning, possibly in conjunction with a suitable etching technique, e.g., a dry etch, such as RF reactive ion etch (RIE) or inductively coupled plasma (ICP) RIE. In various embodiments, any of the etches performed in the method 500 may include an anisotropic etch, using etchants in a form of e.g., chemically active ionized gas (i.e., plasma) using e.g., bromine (Br) and chloride (CI) based chemistries. In some embodiments, during any of the etches of the methods 500, 600, the IC structure may be heated to elevated temperatures, e.g., to temperatures between about room temperature and 200 degrees Celsius, including all values and ranges therein, to promote that byproducts of the etch are made sufficiently volatile to be removed from the surface.

At 502, a semiconductor material may be provided, for example, for an IC structure. The semiconductor material provided at 502 may take the form of any of the embodiments of the semiconductor material 102 disclosed herein, for example (e.g., any of the embodiments discussed herein with reference to a contact arrangement 100, a transistor 300, a device 400). In some examples, the semiconductor material 102 may be doped with N-type dopants (e.g., to form an S/D region for an NMOS transistor). In other examples, the semiconductor material 102 may be doped with P-type dopants (e.g., to form an S/D region for a PMOS transistor). In general, the semiconductor material may be provided at 502 using any suitable deposition and patterning technique known in the art.

At 504, an insulating material may be provided over the semiconductor material. The insulating material provided at 504 may take the form of any of the embodiments of the insulating material 104 disclosed herein. In some examples, the insulating material may be provided at 504 using a technique such as spin-coating, dip-coating, atomic layer deposition (ALD), CVD, or PVD (e.g., evaporative deposition, magnetron sputtering, or e-beam deposition). In general, the insulating material may be provided at 502 using any suitable deposition and patterning technique known in the art.

At 506, a portion of the insulating material may be removed to create an opening through the insulating material to the underlying semiconductor material. The opening 122 may take the form of any of the embodiments of the semiconductor material 102 disclosed herein. In general, the opening may be created at 506 using any suitable etching technique (e.g., a dry etch, such as e.g., RF RIE or inductively coupled plasma (ICP) RIE) in combination with lithography (e.g., photolithography or electron-beam lithography) to define the locations and the sizes of these openings. In some examples, the etches performed as part of 506 to create the opening may include an anisotropic etch, using etchants in a form of e.g., chemically active ionized gas (i.e., plasma) using e.g., bromine (Br) and chloride (CI) based chemistries. In some examples, during the etches at 506, the IC structure may be heated to elevated temperatures, e.g., to temperatures between about room temperature and 200 degrees Celsius, including all values and ranges therein, to promote that byproducts of the etch are made sufficiently volatile to be removed from the surface.

At 508, titanium may be deposited along sidewalls and the bottom of the opening. The titanium deposited at 508 may take the form of any of the embodiments of the second electrically conductive material 106 disclosed herein. In some examples, the titanium may be deposited at 508 using PVD, CVD, or ALD. In general, the titanium may be deposited at 508 using any suitable deposition technique known in the art.

At 510, molybdenum may be deposited on top of the layer of titanium. The molybdenum deposited at 510 may take the form of any of the embodiments of the molybdenum 108 disclosed herein. In some examples, the molybdenum may be deposited using PVD, CVD, or ALD. In general, the molybdenum may be deposited at 510 using any suitable deposition technique known in the art.

At 512, a nitridization process may be performed to incorporate nitrogen into (a surface of) the molybdenum to form a top layer of molybdenum nitride. The nitridized molybdenum may take the form of any of the embodiments of the molybdenum nitride 112 disclosed herein. In some examples, the nitridization process at 512 may include performing a high-temperature PVD, which may include filing nitrogen gas in a chamber, heating the IC structure with the molybdenum in the chamber for some time at a high temperature so that the nitrogen may react with the molybdenum (e.g., in a top surface of the layer of the molybdenum) to form the molybdenum nitride. In other examples, the nitridization process at 512 may include performing a RF/direct current (DC) nitriding process, which may include using an intense electrical field to form nitrogen plasma (ionized nitrogen molecules) on a surface of the molybdenum and subsequently diffuses into the molybdenum to form the molybdenum nitride.

At 514, the remaining portion of the opening created at 506 may be filled with an electrically conductive material to form an electrical contact such that the electrical contact is in contact with the molybdenum nitride formed at 512. The electrically conductive material may take the form of any of the embodiments of the first electrically conductive material 114 disclosed herein. In some examples, the filling of electrically conductive material in the opening at 512 may include performing PVD, CVD, or ALD. In general, the electrically conductive material may fill the opening at 512 using any suitable deposition technique known in the art.

Turning to FIG. 6, generally speaking, the method 600 may include features similar to the method 500 in many respects. For example, operations at 602, 604, 606, 610, 612 are similar to operations at 502, 504, 506, 512, and 514, respectively. Accordingly, for sake of brevity, details of those operations will not be repeated here.

At 602, a semiconductor material may be provided as discussed above with reference to 502. At 604, an insulating material may be provided over the semiconductor material as discussed above with reference to 504. At 606, a portion of the insulating material may be removed to create an opening through the insulating material to the underlying semiconductor material as discussed above with reference to 506.

At 608, molybdenum may be deposited along the sidewalls and the bottom of the opening. The molybdenum may take the form of any of the embodiments of the molybdenum 108 disclosed herein. In some examples, the molybdenum may be deposited using PVD, CVD, or ALD. In general, the molybdenum may be deposited at 606 using any suitable deposition technique known in the art.

At 610, a nitridization process may be performed to incorporate nitrogen into (a surface of) the molybdenum to form a top layer of nitridized molybdenum as discussed above with reference to 512.

At 612, the remaining portion of the opening created at 506 may be filled with an electrically conductive material to form an electrical contact as discussed above with reference to 514.

IC devices with contacts using nitridized molybdenum as disclosed herein may be included in any suitable electronic device. FIGS. 7-11 illustrate various examples of devices and components that may include at least one IC device with one or more electrodes or contacts using nitridized molybdenum as disclosed herein.

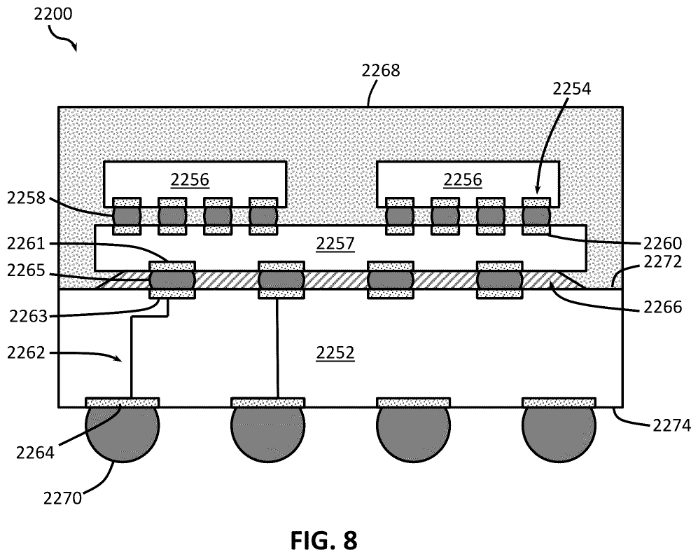

FIG. 7 illustrates top views of a wafer 2000 and dies 2002 that may include one or more IC devices with contacts using nitridized molybdenum in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 8. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., IC devices including at least one contact using nitridized molybdenum as described herein). After the fabrication of the semiconductor product is complete (e.g., after manufacture of at least one contact using nitridized molybdenum as described herein, e.g., after manufacture of any embodiment of the IC devices shown in FIGS. 1-4, or any further embodiments of these devices, described herein), the wafer 2000 may undergo a singulation process in which each of the dies 2002 is separated from one another to provide discrete “chips” of the semiconductor product. In particular, IC devices with contacts using nitridized molybdenum as disclosed herein may take the form of the wafer 2000 (e.g., not singulated) or the form of the die 2002 (e.g., singulated). The die 2002 may include one or more contacts (e.g., one or more contacts 126 and/or 226 as described herein), as well as, optionally, supporting circuitry to route electrical signals to the at least one contact using nitridized molybdenum, as well as any other IC components. In some embodiments, the wafer 2000 or the die 2002 may implement an RF FE device, a memory device (e.g., a static random access memory (SRAM) device), a logic device (e.g., an AND, OR, NAND, or NOR gate), or any other suitable circuit element. Multiple ones of these devices may be combined on a single die 2002.

FIG. 8 is a side, cross-sectional view of an example IC package 2200 that may include one or more IC devices with contacts using nitridized molybdenum in accordance with any of the embodiments disclosed herein. In some embodiments, the IC package 2200 may be a system-in-package (SiP).

As shown in FIG. 8, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

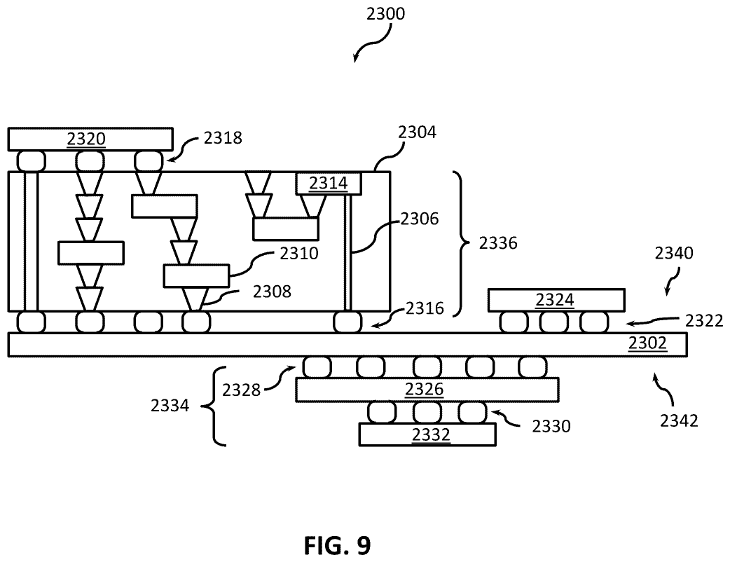

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein and may include any of the embodiments of an IC device having at least one contact using nitridized molybdenum, e.g., any of the IC devices shown in FIGS. 1-4, or any further embodiments of at least one contact using nitridized molybdenum, described herein. In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory). In some embodiments, any of the dies 2256 may include one or more contacts using nitridized molybdenum as discussed above; in some embodiments, at least some of the dies 2256 may not include any electrodes or contacts using nitridized molybdenum.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC devices implementing at least one contact using nitridized molybdenum in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing at least one contact using nitridized molybdenum in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include at least one contact using nitridized molybdenum in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7), an IC device (e.g., the IC device of FIGS. 1-4), or any other suitable component. In particular, the IC package 2320 may include at least one contact using nitridized molybdenum as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing at least one contact using nitridized molybdenum as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

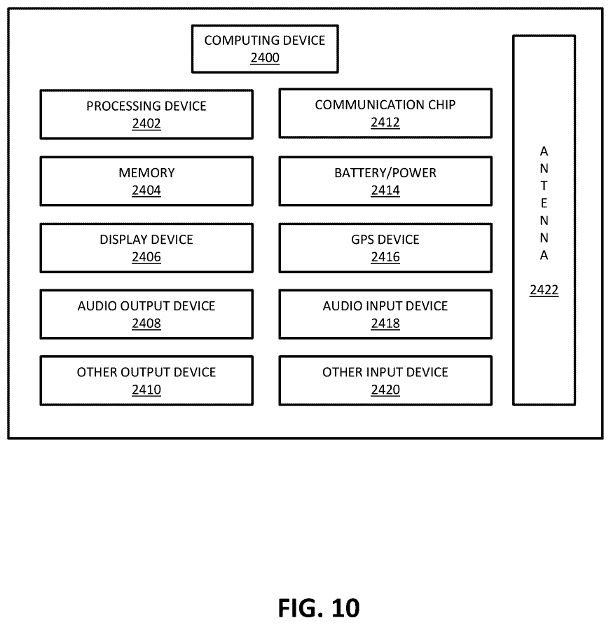

FIG. 10 is a block diagram of an example computing device 2400 that may include one or more components with one or more IC devices having at least one contact using nitridized molybdenum in accordance with any of the embodiments disclosed herein. For example, any suitable ones of the components of the computing device 2400 may include a die (e.g., the die 2002 (FIG. 7)) including at least one contact using nitridized molybdenum in accordance with any of the embodiments disclosed herein. Any of the components of the computing device 2400 may include an IC device (e.g., any embodiment of the IC device of FIGS. 1-4) and/or an IC package 2200 (FIG. 8). Any of the components of the computing device 2400 may include an IC device assembly 2300 (FIG. 9).

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices with at least one contact using nitridized molybdenum as described herein may be particularly advantageous for use within the one or more communication chips 2412, described above. For example, such IC devices with at least one contact using nitridized molybdenum may be used to implement one or more of power amplifiers, low-noise amplifiers, filters (including arrays of filters and filter banks), switches, upconverters, downconverters, and duplexers, e.g., as a part of implementing an RF transmitter, an RF receiver, or an RF transceiver.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

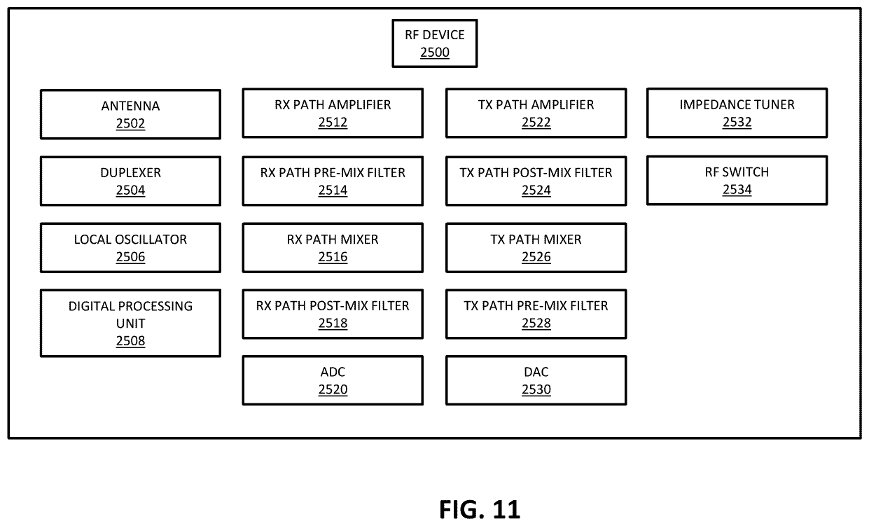

FIG. 11 is a block diagram of an example RF device 2500 that may include one or more components with one or more IC devices having at least one contact using nitridized molybdenum in accordance with any of the embodiments disclosed herein. For example, any suitable ones of the components of the RF device 2500 may include a die (e.g., the die 2002 as described with reference to FIG. 7 or a die implementing the IC device as described with reference to FIGS. 1-4) including at least one contact using nitridized molybdenum in accordance with any of the embodiments disclosed herein. Any of the components of the RF device 2500 may include an IC device (e.g., the IC device of FIGS. 1-4) and/or an IC package 2200 as described with reference to FIG. 8. Any of the components of the RF device 2500 may include an IC device assembly 2300 as described with reference to FIG. 9. In some embodiments, the RF device 2500 may be included within any components of the computing device 2400 as described with reference to FIG. 10, or may be coupled to any of the components of the computing device 2400, e.g., be coupled to the memory 2404 and/or to the processing device 2402 of the computing device 2400. In still other embodiments, the RF device 2500 may further include any of the components described with reference to FIG. 11, such as, but not limited to, the battery/power circuit 2414, the memory 2404, and various input and output devices as shown in FIG. 11.

In general, the RF device 2500 may be any device or system that may support wireless transmission and/or reception of signals in the form of electromagnetic waves in the RF range of approximately 3 kiloHertz (kHz) to 300 gigaHertz (GHz). In some embodiments, the RF device 2500 may be used for wireless communications, e.g., in a BS or a UE device of any suitable cellular wireless communications technology, such as GSM, WCDMA, or LTE. In a further example, the RF device 2500 may be used as, or in, e.g., a BS or a UE device of a mm-wave wireless technology such as fifth generation (5G) wireless (i.e., high frequency/short wavelength spectrum, e.g., with frequencies in the range between about 20 and 60 GHz, corresponding to wavelengths in the range between about 5 and 15 millimeters). In yet another example, the RF device 2500 may be used for wireless communications using WiFi technology (e.g., a frequency band of 2.4 GHz, corresponding to a wavelength of about 12 cm, or a frequency band of 5.8 GHz, spectrum, corresponding to a wavelength of about 5 cm), e.g., in a WiFi-enabled device such as a desktop, a laptop, a video game console, a smart phone, a tablet, a smart TV, a digital audio player, a car, a printer, etc. In some implementations, a WiFi-enabled device may, e.g., be a node in a smart system configured to communicate data with other nodes, e.g., a smart sensor. Still in another example, the RF device 2500 may be used for wireless communications using Bluetooth technology (e.g., a frequency band from about 2.4 to about 2.485 GHz, corresponding to a wavelength of about 12 cm). In other embodiments, the RF device 2500 may be used for transmitting and/or receiving RF signals for purposes other than communication, e.g., in an automotive radar system, or in medical applications such as magneto-resonance imaging (MRI).

In various embodiments, the RF device 2500 may be included in frequency-domain duplexing (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 11 as included in the RF device 2500, but any one or more of these components may be omitted or duplicated, as suitable for the application. For example, in some embodiments, the RF device 2500 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2500 may be an RF device supporting only wireless reception (e.g., an RF receiver), in which case it may include the components of the RX path, but not the components of the TX path; or the RF device 2500 may be an RF device supporting only wireless transmission (e.g., an RF transmitter), in which case it may include the components of the TX path, but not the components of the RX path.

In some embodiments, some or all of the components included in the RF device 2500 may be attached to one or more motherboards. In some embodiments, some or all of these components are fabricated on a single die, e.g., on a single SoC die.

Additionally, in various embodiments, the RF device 2500 may not include one or more of the components illustrated in FIG. 11, but the RF device 2500 may include interface circuitry for coupling to the one or more components. For example, the RF device 2500 may not include an antenna 2502, but may include antenna interface circuitry (e.g., a matching circuitry, a connector and driver circuitry) to which an antenna 2502 may be coupled. In another set of examples, the RF device 2500 may not include a digital processing unit 2508 or a local oscillator 2506, but may include device interface circuitry (e.g., connectors and supporting circuitry) to which a digital processing unit 2508 or a local oscillator 2506 may be coupled.

As shown in FIG. 11, the RF device 2500 may include an antenna 2502, a duplexer 2504, a local oscillator 2506, a digital processing unit 2508. As also shown in FIG. 11, the RF device 2500 may include an RX path which may include an RX path amplifier 2512, an RX path pre-mix filter 2514, a RX path mixer 2516, an RX path post-mix filter 2518, and an analog-to-digital converter (ADC) 2520. As further shown in FIG. 11, the RF device 2500 may include a TX path which may include a TX path amplifier 2522, a TX path post-mix filter 2524, a TX path mixer 2526, a TX path pre-mix filter 2528, and a digital-to-analog converter (DAC) 2530. Still further, the RF device 2500 may further include an impedance tuner 2532 and an RF switch 2534. In various embodiments, the RF device 2500 may include multiple instances of any of the components shown in FIG. 11. The RX path amplifier 2512, the TX path amplifier 2522, the duplexer 2504, and the RF switch 2534 may be considered to form, or be a part of, an RF FE of the RF device 2500. The RX path mixer 2516 and the TX path mixer 2526 (possibly with their associated pre-mix and post-mix filters shown in FIG. 11) may be considered to form, or be a part of, an RF transceiver of the RF device 2500 (or of an RF receiver or an RF transmitter if only RX path or TX path components, respectively, are included in the RF device 2500).

The antenna 2502 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2500 is an FDD transceiver, the antenna 2502 may be configured for concurrent reception and transmission of communication signals in separate, i.e., non-overlapping and non-continuous, bands of frequencies, e.g. in bands having a separation of, e.g., 20 MHz from one another. If the RF device 2500 is a TDD transceiver, the antenna 2502 may be configured for sequential reception and transmission of communication signals in bands of frequencies which may be the same, or overlapping for TX and RX paths. In some embodiments, the RF device 2500 may be a multi-band RF device, in which case the antenna 2502 may be configured for concurrent reception of signals having multiple RF components in separate frequency bands and/or configured for concurrent transmission of signals having multiple RF components in separate frequency bands. In such embodiments, the antenna 2502 may be a single wide-band antenna or a plurality of band-specific antennas (i.e., a plurality of antennas each configured to receive and/or transmit signals in a specific band of frequencies). In various embodiments, the antenna 2502 may include a plurality of antenna elements, e.g., a plurality of antenna elements forming a phased antenna array (i.e., a communication system or an array of antennas that may use a plurality of antenna elements and phase shifting to transmit and receive RF signals). Compared to a single-antenna system, a phased antenna array may offer advantages such as increased gain, ability of directional steering, and simultaneous communication. In some embodiments, the RF device 2500 may include more than one antenna 2502 to implement antenna diversity. In some such embodiments, the RF switch 2534 may be deployed to switch between different antennas.

An output of the antenna 2502 may be coupled to the input of the duplexer 2504. The duplexer 2504 may be any suitable component configured for filtering multiple signals to allow for bidirectional communication over a single path between the duplexer 2504 and the antenna 2502. The duplexer 2504 may be configured for providing RX signals to the RX path of the RF device 2500 and for receiving TX signals from the TX path of the RF device 2500.

The RF device 2500 may include one or more local oscillators 2506, configured to provide local oscillator signals which may be used for downconversion of the RF signals received by the antenna 2502 and/or upconversion of the signals to be transmitted by the antenna 2502.

The RF device 2500 may include the digital processing unit 2508, which may include one or more processing devices. In some embodiments, the digital processing unit 2508 may be implemented as the processing device 2402 shown in FIG. 10, descriptions of which are provided above (when used as the digital processing unit 2508, the processing device 2402 may, but does not have to, implement any of the IC devices as described herein, e.g., IC devices having at least one contact using nitridized molybdenum in accordance with any of the embodiments disclosed herein). The digital processing unit 2508 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 11, in some embodiments, the RF device 2500 may further include a memory device, e.g., the memory device 2404 as described with reference to FIG. 11, configured to cooperate with the digital processing unit 2508. When used within, or coupled to, the RF device 2500, the memory device 2404 may, but does not have to, implement any of the IC devices as described herein, e.g., IC devices having at least one contact using nitridized molybdenum in accordance with any of the embodiments disclosed herein.

Turning to the details of the RX path that may be included in the RF device 2500, the RX path amplifier 2512 may include a low noise amplifier (LNA). An input of the RX path amplifier 2512 may be coupled to an antenna port (not shown) of the antenna 2502, e.g., via the duplexer 2504. The RX path amplifier 2512 may amplify the RF signals received by the antenna 2502.

An output of the RX path amplifier 2512 may be coupled to an input of the RX path pre-mix filter 2514, which may be, e.g., a harmonic or band-pass filter, configured to filter received RF signals that have been amplified by the RX path amplifier 2512.

An output of the RX path pre-mix filter 2514 may be coupled to an input of the RX path mixer 2516, also referred to as a downconverter. The RX path mixer 2516 may include two inputs and one output. A first input may be configured to receive the RX signals, which may be current signals, indicative of the signals received by the antenna 2502 (e.g., the first input may receive the output of the RX path pre-mix filter 2514). A second input may be configured to receive local oscillator signals from one of the local oscillators 2506. The RX path mixer 2516 may then mix the signals received at its two inputs to generate a downconverted RX signal, provided at an output of the RX path mixer 2516. As used herein, downconversion refers to a process of mixing a received RF signal with a local oscillator signal to generate a signal of a lower frequency. In particular, the downconverter 2516 may be configured to generate the sum and/or the difference frequency at the output port when two input frequencies are provided at the two input ports. In some embodiments, the RF device 2500 may implement a direct-conversion receiver (DCR), also known as homodyne, synchrodyne, or zero-IF receiver, in which case the RX path mixer 2516 may be configured to demodulate the incoming radio signals using local oscillator signals whose frequency is identical to, or very close to the carrier frequency of the radio signal. In other embodiments, the RF device 2500 may make use of downconversion to an intermediate frequency (IF). IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2516 may include several such stages of IF conversion.

Although a single RX path mixer 2516 is shown in the RX path of FIG. 11, in some embodiments, the RX path mixer 2516 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2502 and an in-phase component of the local oscillator signal provided by the local oscillator 2506. The second RX path mixer may be configured for performing downconversion to generate a quadrature (Q) downconverted RX signal by mixing the RX signal received by the antenna 2502 and a quadrature component of the local oscillator signal provided by the local oscillator 2506 (the quadrature component is a component that is offset in phase from the in-phase component of the local oscillator signal by 90 degrees). The output of the first RX path mixer may be provided to a I-signal path, and the output of the second RX path mixer may be provided to a Q-signal path, which may be substantially 90 degrees out of phase with the I-signal path.

The output of the RX path mixer 2516 may, optionally, be coupled to the RX path post-mix filter 2518, which may be low-pass filters. In case the RX path mixer 2516 is a quadrature mixer that implements the first and second mixers as described above, the in-phase and quadrature components provided at the outputs of the first and second mixers respectively may be coupled to respective individual first and second RX path post-mix filters included in the filter 2518.

The ADC 2520 may be configured to convert the mixed RX signals from the RX path mixer 2516 from analog to digital domain. The ADC 2520 may be a quadrature ADC that, similar to the RX path quadrature mixer 2516, may include two ADCs, configured to digitize the downconverted RX path signals separated in in-phase and quadrature components. The output of the ADC 2520 may be provided to the digital processing unit 2508, configured to perform various functions related to digital processing of the RX signals so that information encoded in the RX signals can be extracted.

Turning to the details of the TX path that may be included in the RF device 2500, the digital signal to later be transmitted (TX signal) by the antenna 2502 may be provided, from the digital processing unit 2508, to the DAC 2530. Similar to the ADC 2520, the DAC 2530 may include two DACs, configured to convert, respectively, digital I- and Q-path TX signal components to analog form.

Optionally, the output of the DAC 2530 may be coupled to the TX path pre-mix filter 2528, which may be a low-pass filter (or a pair of filters, in case of quadrature processing) configured to filter out, from the analog TX signals output by the DAC 2530, the signal components outside of the desired band. The digital TX signals may then be provided to the TX path mixer 2526, which may also be referred to as an upconverter. Similar to the RX path mixer 2516, the TX path mixer 2526 may include a pair of TX path mixers, for in-phase and quadrature component mixing. Similar to the first and second RX path mixers that may be included in the RX path, each of the TX path mixers of the TX path mixer 2526 may include two inputs and one output. A first input may receive the TX signal components, converted to the analog form by the respective DAC 2530, which are to be upconverted to generate RF signals to be transmitted. The first TX path mixer may generate an in-phase (I) upconverted signal by mixing the TX signal component converted to analog form by the DAC 2530 with the in-phase component of the TX path local oscillator signal provided from the local oscillator 2506 (in various embodiments, the local oscillator 2506 may include a plurality of different local oscillators, or be configured to provide different local oscillator frequencies for the mixer 2516 in the RX path and the mixer 2526 in the TX path). The second TX path mixer may generate a quadrature phase (Q) upconverted signal by mixing the TX signal component converted to analog form by the DAC 2530 with the quadrature component of the TX path local oscillator signal. The output of the second TX path mixer may be added to the output of the first TX path mixer to create a real RF signal. A second input of each of the TX path mixers may be coupled the local oscillator 2506.

Optionally, the RF device 2500 may include the TX path post-mix filter 2524, configured to filter the output of the TX path mixer 2526.

The TX path amplifier 2522 may be a power amplifier (PA), configured to amplify the upconverted RF signal before providing it to the antenna 2502 for transmission.

In various embodiments, any of the RX path pre-mix filter 2514, the RX path post-mix filter 2518, the TX post-mix filter 2524, and the TX pre-mix filter 2528 may be implemented as RF filters. In some embodiments, each of such RF filters may include one or more, typically a plurality of, resonators (e.g., film bulk acoustic resonators (FBARs), Lamb wave resonators, and/or contour-wave resonators), arranged, e.g., in a ladder configuration. An individual resonator of an RF filter may include a layer of a piezoelectric material such as aluminum nitride (AlN), enclosed between a bottom electrode and a top electrode, with a cavity provided around a portion of each electrode in order to allow a portion of the piezoelectric material to vibrate during operation of the filter. In some embodiments, an RF filter may be implemented as a plurality of RF filters, or a filter bank. A filter bank may include a plurality of RF resonators which may be coupled to a switch, e. g., the RF switch 2534, configured to selectively switch any one of the plurality of RF resonators on and off (i.e., activate any one of the plurality of RF resonators), in order to achieve desired filtering characteristics of the filter bank (i.e., in order to program the filter bank). For example, such a filter bank may be used to switch between different RF frequency ranges when the RF device 2500 is, or is included in, a BS or in a UE device. In another example, such a filter bank may be programmable to suppress TX leakage on the different duplex distances.

The impedance tuner 2532 may include any suitable circuitry, configured to match the input and output impedances of the different RF circuitries to minimize signal losses in the RF device 2500. For example, the impedance tuner 2532 may include an antenna impedance tuner. Being able to tune the impedance of the antenna 2502 may be particularly advantageous because antenna's impedance is a function of the environment that the RF device 2500 is in, e.g., antenna's impedance changes depending on, e.g., if the antenna is held in a hand, placed on a car roof, etc.

As described above, the RF switch 2534 may be used to selectively switch between a plurality of instances of any one of the components shown in FIG. 11, in order to achieve desired behavior and characteristics of the RF device 2500. For example, in some embodiments, an RF switch may be used to switch between different antennas 2502. In other embodiments, an RF switch may be used to switch between a plurality of RF resonators (e.g., by selectively switching RF resonators on and off) of any of the filters included in the RF device 2500.

In various embodiments, IC devices including one or more contacts using nitridized molybdenum as described herein may be particularly advantageous when used in any of the duplexer 2504, RX path amplifier 2512, RX path pre-mix filter 2514, RX path post-mix filter 2518, TX path amplifier 2522, TX path pre-mix filter 2528, TX path post-mix filter 2524, impedance tuner 2532, and/or RF switch 2534.

The RF device 2500 provides a simplified version and, in further embodiments, other components not specifically shown in FIG. 11 may be included. For example, the RX path of the RF device 2500 may include a current-to-voltage amplifier between the RX path mixer 2516 and the ADC 2520, which may be configured to amplify and convert the downconverted signals to voltage signals. In another example, the RX path of the RF device 2500 may include a balun transformer for generating balanced signals. In yet another example, the RF device 2500 may further include a clock generator, which may, e.g., include a suitable phase-locked-loop (PLL), configured to receive a reference clock signal and use it to generate a different clock signal which may then be used for timing the operation of the ADC 2520, the DAC 2530, and/or which may also be used by the local oscillator 2506 to generate the local oscillator signals to be used in the RX path or the TX path.

The following paragraphs provide various examples of the embodiments disclosed herein.

Example 1 provides an integrated circuit (IC) device, including a semiconductor material; a contact (an electrically conductive contact) in an opening of the insulating material extending to a portion of the semiconductor material, the contact including molybdenum, where the contact includes a fill material and molybdenum, and the molybdenum is between the fill material and the insulating material.

Example 2 provides the IC device according to example 1, where the molybdenum is in a layer having a thickness between about 5 and 16 nanometers (e.g., between about 6 and 10 nm or 5 and 11 nm (when a titanium (Ti) layer is also included, see FIG. 1), between about 10 and 15 nm, or between about 9 and 16 nm (when only molybdenum (Mo) is included, see FIG. 2)).

Example 3 provides the IC device according to any one of examples 1-2, where an atomic percentage of molybdenum in the layer is at least about 80%, e.g., between about 80% and 100%, between about 90% and 100% or between about 95% and 100%.

Example 4 provides the IC device according to any one of examples 2-3, where the fill material includes an electrically conductive material and the layer is at least on sidewalls (possibly also at the bottom) of the opening.

Example 5 provides the IC device according to example 4, where the layer is a first layer, molybdenum is further in a second layer, the second layer having a thickness between about 0.5 and 2.5 nanometers (e.g., between 1 and 2 nm) and further including nitrogen, and the second layer is between the first layer and the fill material.

Example 6 provides the IC device according to example 5, where the second layer is in contact with the fill material.

Example 7 provides the IC device according to any one of examples 5-6, where an atomic percentage of nitrogen in the second layer is at least about 20%, e.g., between about 20% and 40%, or between 25% and 35%.

Example 8 provides the IC device according to any one of examples 5-7, where an atomic percentage of molybdenum in the second layer is at least about 60%, e.g., between about 60% and 80% or between about 65% and 75%.

Example 9 provides the IC device according to any one of examples 2 or 3, where the fill material includes a first electrically conductive material, the contact further includes a second electrically conductive material, and the second electrically conductive material is at least on sidewalls (possibly also at the bottom) of the opening and is between the first electrically conductive material and the layer, the layer is between the second electrically conductive material and the first electrically conductive material.

Example 10 provides the IC device according to example 9, where the second electrically conductive material includes titanium.

Example 11 provides the IC device according to any one of examples 9-10, where the layer is a first layer, molybdenum is further in a second layer, the second layer having a thickness between about 0.5 and 2.5 nanometers (e.g., between 1 and 2 nm) and further including nitrogen, and the second layer is between the first layer and the first electrically conductive material.

Example 12 provides the IC device according to example 11, where the second layer is in contact with the first electrically conductive material.

Example 13 provides the IC device according to any one of examples 11-12, where an atomic percentage of nitrogen in the second layer is at least about 20%, e.g., between about 20% and 40% or between 25% and 35%.

Example 14 provides the IC device according to any one of examples 11-13, where an atomic percentage of molybdenum in the second layer is at least about 60%, e.g., between about 60% and 80% or between about 65% and 75%.

Example 15 provides the IC device according to any one of examples 1-14, where the semiconductor material has a shape of a fin (e.g., as discussed above with reference to FIGS. 4A-4B).

Example 16 provides the IC device according to any one of examples 1-14, further including a transistor, where the semiconductor material is the transistor and includes P-type dopants or N-type dopants.

Example 17 provides an integrated circuit (IC) device including a transistor including a semiconductor material, a source electrode, and a drain electrode, where at least one of the source electrode or the drain electrode includes a fill material and molybdenum, the fill material includes an electrically conductive material, the molybdenum is in a first layer and a second layer, the second layer further includes nitrogen, and the second layer is between the first layer and the fill material and in contact with the fill material.

Example 18 provides the IC device according to example 17, where the transistor further includes an insulating material and the at least one of the source electrode or the drain electrode is in an opening of the insulating material.

Example 19 provides the IC device according to example 18, where the first layer is at least on sidewalls (possibly also at the bottom) of the opening and is between the insulating material and the fill material.

Example 20 provides the IC device according to example 18, where the electrically conductive material is a first electrically conductive material, the at least one of the source electrode or the drain electrode further includes a second electrically conductive material, the second electrically conductive material is at least on sidewalls (possibly also at the bottom) of the opening, and the first layer is between the first electrically conductive material and the second electrically conductive material.

Example 21 provides the IC device according to example 20, where the second electrically conductive material includes titanium.

Example 22 provides the IC device according to any one of examples 17-21, where the transistor further includes a channel material, and a gate electrode, the semiconductor material is at least partially enclosed within the channel material, and the at least one of the source electrode or the drain electrode and the gate electrode are on one side of the channel material.

Example 23 provides the IC device according to any one of examples 17-21, where the transistor further includes a channel material, and a gate electrode, the semiconductor material is at least partially enclosed within the semiconductor channel material, the one of the source electrode or the drain electrode is on one side of the channel material, and the gate electrode is on another side of the channel material.

Example 24 provides the IC device according to any one of examples 17-21, where the transistor further includes a channel material, the semiconductor material is at least partially enclosed within the channel material, the source electrode is one side of the channel material, and the drain electrode is on another side of the channel material.

Example 25 provides a method of manufacturing an integrated circuit (IC) device, the method including providing a semiconductor material; providing an insulating material over the semiconductor material; removing a portion of the insulating material to create an opening through the insulating material to the semiconductor material; depositing a layer of molybdenum along sidewalls and a bottom of the opening; performing a nitridation process to incorporate nitrogen into the layer of molybdenum; and filling the opening with an electrically conductive material after performing the nitridation process.

Example 26 provide the method according to example 24, further including depositing a layer of titanium along the sidewalls and the bottom of the opening before depositing the layer of molybdenum.

Example 27 provides the IC device according to any one of the preceding examples, where the IC device includes or is a part of a central processing unit.

Example 28 provides the IC device according to any one of the preceding examples, where the IC device includes or is a part of a memory device.

Example 29 provides the IC device according to any one of the preceding examples, where the IC device further includes a plurality of memory cells, each of the memory cells including a storage element.

Example 30 provides the IC device according to example 29, where the storage element is one of a capacitor, a magnetoresistive material, a ferroelectric material, or a resistance-changing material.

Example 31 provides the IC device according to any one of the preceding examples, where the IC device includes or is a part of a logic circuit.

Example 32 provides the IC device according to any one of the preceding examples, where the IC device includes or is a part of input/output circuitry.

Example 33 provides the IC device according to any one of the preceding examples, where the IC device includes or is a part of a field programmable gate array transceiver.

Example 34 provides the IC device according to any one of the preceding examples, where the IC device includes or is a part of a field programmable gate array logic.

Example 35 provides the IC device according to any one of the preceding examples, where the IC device includes or is a part of a power delivery circuitry.

Example 36 provides the IC device according to any one of the preceding examples, where the IC device includes or is a part of a III-V amplifier.

Example 37 provides the IC device according to any one of the preceding examples, where the IC device includes or is a part of Peripheral Component Interconnect Express circuitry or Double Data Rate transfer circuitry.

Example 38 provides an IC package that includes a die including an IC device according to any one of the preceding examples; and a further IC component, coupled to the die.

Example 39 provides the IC package according to example 38, where the further IC component includes one of a package substrate, an interposer, or a further IC support structure.

Example 40 provides a computing device that includes a carrier substrate and an IC device, coupled to the carrier substrate, where the IC device is an IC device according to any one of the preceding examples, or the IC device is included in the IC package according to any one of examples 38-39.

Example 41 provides the computing device according to example 40, where the computing device is a wearable or handheld computing device.

Example 42 provides the computing device according to examples 40 or 41, where the computing device further includes one or more communication chips and an antenna.

Example 43 provides the computing device according to any one of examples 40-42, where the carrier substrate is a motherboard.

Example 44 provides a method of manufacturing an IC device, the method including providing the IC device according to any one of the preceding examples.

1. An integrated circuit (IC) device, comprising:
a semiconductor material;
an insulating material; and
a contact in an opening of the insulating material and extending to a portion of the semiconductor material,
wherein:
the contact includes a fill material and molybdenum, and
the molybdenum is between the fill material and the insulating material.

2. The IC device according to claim 1, wherein the molybdenum is in a layer having a thickness between about 5 and 16 nanometers.

3. The IC device according to claim 2, wherein an atomic percentage of molybdenum in the layer is at least about 80%.

4. The IC device according to claim 2, wherein:
the fill material includes an electrically conductive material, and
the layer is at least on sidewalls of the opening.

5. The IC device according to claim 4, wherein:
the layer is a first layer,
molybdenum is further in a second layer, the second layer having a thickness between about 0.5 and 2.5 nanometers and further including nitrogen, and
the second layer is between the first layer and the fill material.

6. The IC device according to claim 5, wherein the second layer is in contact with the fill material.

7. The IC device according to claim 5, wherein an atomic percentage of nitrogen in the second layer is at least about 20%.

8. The IC device according to claim 5, wherein an atomic percentage of molybdenum in the second layer is at least about 60%.

9. The IC device according to claim 2, wherein:
the fill material includes a first electrically conductive material,
the contact further includes a second electrically conductive material,
the second electrically conductive material is at least on sidewalls of the opening and is between the first electrically conductive material and the layer, and
the layer is between the second electrically conductive material and the first electrically conductive material.

10. The IC device according to claim 9, wherein the second electrically conductive material includes titanium.

11. The IC device according to claim 9, wherein:
the layer is a first layer,
molybdenum is further in a second layer, the second layer having a thickness between about 0.5 and 2.5 nanometers and further including nitrogen, and
the second layer is between the first layer and the first electrically conductive material.

12. The IC device according to claim 11, wherein the second layer is in contact with the first electrically conductive material.

13. The IC device according to claim 1, wherein the semiconductor material has a shape of a fin.

14. An integrated circuit (IC) device comprising:
a transistor comprising:
a semiconductor material,
a source electrode, and
a drain electrode,
wherein:
at least one of the source electrode or the drain electrode includes a fill material and molybdenum,
the fill material includes an electrically conductive material,
the molybdenum is in a first layer and a second layer,
the second layer further includes nitrogen, and
the second layer is between the first layer and the fill material and in contact with the fill material.

15. The IC device according to claim 14, wherein:
the transistor further includes an insulating material, and
the at least one of the source electrode or the drain electrode is in an opening of the insulating material.

16. The IC device according to claim 15, wherein the first layer is at least on sidewalls of the opening and is between the insulating material and the fill material.

17. The IC device according to claim 15, wherein:
the electrically conductive material is a first electrically conductive material,
the at least one of the source electrode or the drain electrode further includes a second electrically conductive material,
the second electrically conductive material is at least on sidewalls of the opening, and
the first layer is between the first electrically conductive material and the second electrically conductive material.

18. The IC device according to claim 17, wherein the second electrically conductive material includes titanium.

19. A method of manufacturing an integrated circuit (IC) device, the method comprising:
providing a semiconductor material;
providing an insulating material over the semiconductor material;
removing a portion of the insulating material to create an opening through the insulating material to the semiconductor material;
depositing a layer of molybdenum along sidewalls and a bottom of the opening;
performing a nitridation process to incorporate nitrogen into the layer of molybdenum; and
filling the opening with an electrically conductive material after performing the nitridation process.

20. The method according to claim 19, further comprising:
depositing a layer of titanium along the sidewalls and the bottom of the opening before depositing the layer of molybdenum.
